(19) United States
(12) Patent Application Publication
(10) Pub. No.: US 2019/0226495 A1
(43) Pub. Date: Jul. 25, 2019

(54) BLOWER DEVICE

(71) Applicant: NIDEC COPAL ELECTRONICS CORPORATION, Tokyo (JP)

(72) Inventors: Takashi KANAI, Sano-shi (JP); Hiroki MATSUSHITA, Sano-shi (JP)

(73) Assignee: NIDEC COPAL ELECTRONICS CORPORATION, Tokyo (JP)

(21) Appl. No.: 16/372,900

(22) Filed: Apr. 2, 2019

Related U.S. Application Data
(63) Continuation of application No. PCT/JP2017/035337, filed on Sep. 28, 2017.

(30) Foreign Application Priority Data
Dec. 5, 2016 (JP) 2016236084

(51) Int. Cl. F04D 29/58; F04D 17/16; F04D 25/06; H02K 5/18; H02K 5/20; H02K 9/06; H02K 11/33

(52) U.S. Cl. CPC F04D 29/5806; F04D 17/16; F04D 25/06; F04D 29/584; H05K 1/181; H02K 5/20; H02K 9/06; H02K 11/33; H02K 2211/03; H02K 5/18

(57) ABSTRACT

A blower device includes a housing including an intake chamber configured to take in external air from an intake port, an accommodation chamber communicating with the intake chamber through an opening, and an exhaust port configured to discharge the air inside the accommodation chamber to the outside, a motor provided in the accommodation chamber of the housing and including a coil, a fan provided on a rotating shaft of the motor and configured to introduce the air inside the intake chamber from the opening into the accommodation chamber and blow the air from the accommodation chamber to the exhaust port, a sealing member configured to seal up the intake chamber, and a circuit board which is provided above the sealing member and on which circuit components configured to drive the motor are arranged.

### CROSS-REFERENCE TO RELATED APPLICATIONS

This application is a continuation of International Application No. PCT/JP2017/035337, filed on Sep. 28, 2017, which claims priority to and the benefit of JP 2016-236084 filed on Dec. 5, 2016. The disclosures of the above applications are incorporated herein by reference.

### FIELD

The present disclosure relates to a blower device.

### BACKGROUND

The statements in this section merely provide background information related to the present disclosure and may not constitute prior art.

In general, a blower device configured to discharge air taken in from an intake port to an exhaust port includes, for example, a fan, motor configured to drive the fan, and circuit board on which circuit components such as a Metal Oxide Semiconductor-Field Effect Transistor (MOS-FET) and the like configured to drive the motor are arranged (see, for example, Patent Literature 1).

However, in a blower device of such a kind, when a circuit board on which circuit components such as a MOS-FET and the like are arranged is arranged in the vicinity of a motor, the MOS-FET and the like generate a large amount of heat during an operation of the blower device, and hence a coil arranged in the motor is heated by the generated heat. When the temperature of the motor coil is raised by the heating, the drive efficiency of the motor relative to the supplied electric power lowers, and hence the output (blast pressure and blast flow rate) of the blower device lowers.

Moreover, the heat generation itself of the coil becomes a hindrance to the heat radiation of the periphery of the motor, and hence the coil temperature of the motor unnecessarily rises. Accordingly, when the motor is driven within an allowable temperature range, the output of the blower device lowers.

### CITATION LIST

### Patent Literature

Patent Literature 1: JP 2007-154776 A

### SUMMARY

Embodiments described herein aim to provide a blower device capable of suppressing a rise in the coil temperature of the motor, and preventing the output thereof from lowering.

A blower device according to an embodiment includes a housing including an intake chamber configured to take in external air from an intake port, an accommodation chamber communicating with the intake chamber through an opening, and an exhaust port configured to discharge the air inside the accommodation chamber to the outside; a motor provided in the accommodation chamber of the housing and including a coil; a fan provided on a rotating shaft of the motor and configured to introduce the air inside the intake chamber from the opening into the accommodation chamber and blow the air from the accommodation chamber to the exhaust port; a sealing member configured to seal up the intake chamber; and a circuit board which is provided above the sealing member and on which circuit components configured to drive the motor are arranged.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

Further areas of applicability will become apparent from the description provided herein. It should be understood that the description and specific examples are intended for purposes of illustration only and are not intended to limit the scope of the present disclosure.

### DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing the overall configuration of a blower device according to a first embodiment.

FIG. 2 is a cross-sectional view of the blower device viewed from the arrow direction along line II-II of FIG. 1.

FIG. 3A is an exploded perspective view showing part of the blower device according to the first embodiment.

FIG. 3B is a top view showing part of the blower device according to the first embodiment.

FIG. 4A is an exploded perspective view showing part of the blower device according to the first embodiment.

FIG. 4B is a top view showing part of the blower device according to the first embodiment.

FIG. 5A is an exploded perspective view showing part of the blower device according to the first embodiment.

FIG. 5B is a top view showing part of the blower device according to the first embodiment.

FIG. 6A is an exploded perspective view showing part of the blower device according to the first embodiment.

FIG. 6B is a top view showing part of the blower device according to the first embodiment.

FIG. 7A is an exploded perspective view showing part of the blower device according to the first embodiment.

FIG. 7B is a top view showing part of the blower device according to the first embodiment.

FIG. 8 is a block diagram schematically showing the electrical configuration of the control system of the blower device according to the first embodiment.

FIG. 9 is a flowchart showing the flow paths of the air-blowing operation to be carried out by the blower device according to the first embodiment.

FIG. 10 is a cross-sectional view for explaining the main flow path of FIG. 9.

FIG. 11 is a cross-sectional view for explaining the bypass flow path of FIG. 9.

FIG. 12 is a cross-sectional view showing a blower device according to a second embodiment.

The drawings described herein are for illustration purposes only and are not intended to limit the scope of the present disclosure in any way.

### DETAILED DESCRIPTION

Embodiments of the present invention will be described below with reference to the accompanying drawings. It should be noted that in the following descriptions, functions and elements substantially identical to each other are denoted by identical reference numbers and are described as the need arises. Further, the drawings are schematic, and relationships between the thickness and planar dimensions, ratios of the thickness of each layer, and like may sometimes differ from those in the actual case.

### First Embodiment

[Configuration]

[Overall Configuration]

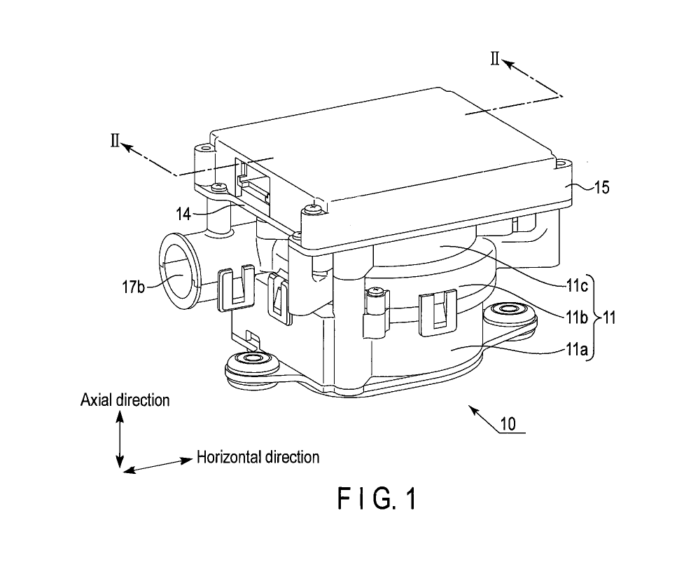

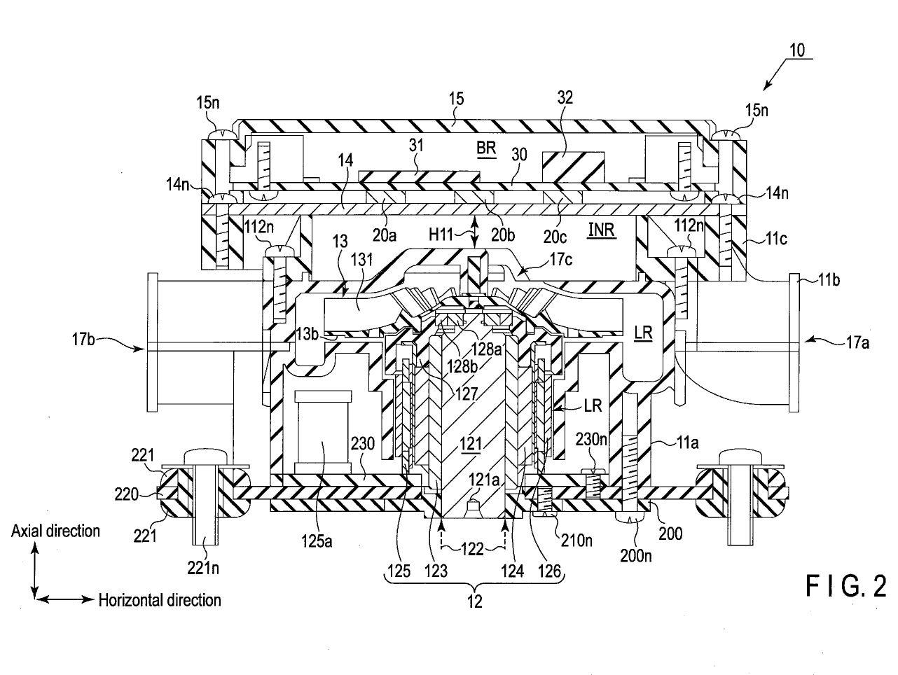

The overall configuration of a blower device 10 according to a first embodiment will be described below by using FIG. 1 and FIG. 2. FIG. 1 is a perspective view showing the overall configuration of the blower device 10 according to the first embodiment. FIG. 2 is a cross-sectional view of the blower device 10 viewed from the arrow direction along line II-II of FIG. 1.

As shown in FIG. 1 and FIG. 2, the blower device 10 according to the first embodiment includes a housing 11, intake cover (sealing member) 14 configured to seal up an intake chamber INR provided inside the housing 11, and board cover 15. The housing 11 is constituted of three divided housing members 11a to 11c. The housing 11 includes an intake port 17a and exhaust port 17b. As will be described later, the intake port 17a is constituted of the housing members 11a and 11c, and exhaust port 17b is constituted of the housing members 11a and 11b. Inside the housing 11, an accommodation chamber LR communicating with the intake port 17a and exhaust port 17b and configured to accommodate therein a fan unit 51 is provided. The fan unit 51 includes a fan 13 and motor 12 configured to drive the fan 13.

The intake cover (sealing member) 14 is provided on the housing member 11c, and the housing member 11c and intake cover 14 constitute the intake chamber INR. The intake cover 14 is constituted of a material having excellent thermal conductivity such as aluminum, and functions as a heat sink.

A circuit board 30 is provided above the intake cover 14. Circuit components including a power MOS-FET 32 configured to drive the motor 12 and control circuit 31 configured to control the operation of the power MOS-FET 32 are arranged on the circuit board 30.

A plurality of plate-like heat sinks (heat-radiation members) 20a to 20c are provided between the intake cover 14 and circuit board 30. More specifically, the heat sink 20a is arranged beneath the control circuit 31, heat sink 20b is arranged beneath the control circuit 31 and at a central part in the vicinity of an opening 17c, and heat sink 20c is arranged beneath the power MOS-FET 32. The heat sinks 20a to 20c are constituted of a material excellent in the thermal conductivity such as aluminum. Undersurfaces of the heat sinks 20a to 20c are, for example, pressure-welded to the top surface of the intake cover 14. Top surfaces of the heat sinks 20a to 20c are, for example, pressure-welded to the undersurface of the circuit board 30. The heat sinks 20a to 20c conduct heat generated from the control circuit 31 and power MOS-FET 32 arranged on the circuit board 30 to the intake cover 14.

The board cover 15 is attached to the intake cover 14. The circuit board 30 is covered with the board cover 15. The board cover 15 may be constituted of a material excellent in thermal conductivity such as aluminum.

It should be noted that the housing member 11a is provided on a base plate 200 arranged at the bottom part. An attaching member 220 configured to attach the blower device 10 to a predetermined position is provided on the base plate 200. The base plate 200 and attaching member 220 are fixed to each other with an attaching screw 210n penetrating the base plate 200 and attaching member 220. The attaching member 220 and a coil board 230 are fixed to each other with an attaching screw 230n penetrating the attaching member 220 and coil board 230. The base plate 200, attaching member 220, and housing member 11a are fixed to each other with an attaching screw 200n penetrating these three members. Further, cushion rubbers 221 sandwiching the top surface and undersurface of the attaching member 220 are arranged at ends of the attaching member 220. The blower device 10 is configured in such a manner that the blower device 10 can be attached to an arbitrary position by fixing attaching screws 221n penetrating the attaching member 220 and cushion rubbers 221 to predetermined attaching positions.

The motor 12 is, for example, a coreless motor. The motor 12 includes at least a shaft (rotating shaft) 121, minute gap 122, sleeve 123, magnet 124, coil 125, fixed yoke 126, hub 127, and thrust magnets 128a and 128b.

The shaft 121 is fixed to the base plate 200 with an attaching screw 121a. The minute gap 122 is a very small gap provided between the shaft 121 and sleeve 123. The sleeve 123 is provided at an outer circumferential part of the shaft 121 through the minute gap 122. The magnet 124 is provided at an outer circumferential part of the sleeve 123. The coil 125 is provided at an outer circumferential part of the magnet 124. The fixed yoke 126 is provided at an outer circumferential part of the coil 125 in order to form a predetermined magnetic circuit. The hub 127 is a rotary member configured to support the sleeve 123 and magnet 124 and cover the upper part of the shaft 121. The thrust magnet 128a is a ring-like magnet fixed to the upper part of the shaft 121. The thrust magnet 128b is a ring-like magnet fixed to the upper part of the hub 127 so as to the face aforementioned thrust magnet 128a. In this embodiment, the air dynamic pressure bearing is constituted of the above-mentioned configuration.

It should be noted that in the vicinity of the motor 12, a separate coil 125a is provided as an inductor electrically connected to the coil 125 through the coil board 230. Further, a reinforcing ring configured to prevent the magnet 124 from being broken by the centrifugal force due to the rotation of the fan 13 is provided between the magnet 124 and coil 125.

The fan 13 is arranged in the accommodation chamber LR, and is fixed to the hub 127 functioning as the rotary member. The fan 13 includes a plurality of fan blades 131 configured to blow the air introduced into the intake chamber INR from the intake port 17a to the exhaust port 17b through the opening 17c with a predetermined output (blast pressure and blast flow rate). The plurality of fan blades 131 are provided on the top surface of the fan 13 at predetermined intervals, and each of the fan blades 131 is constituted of a plate-like member protruding in the axial direction.

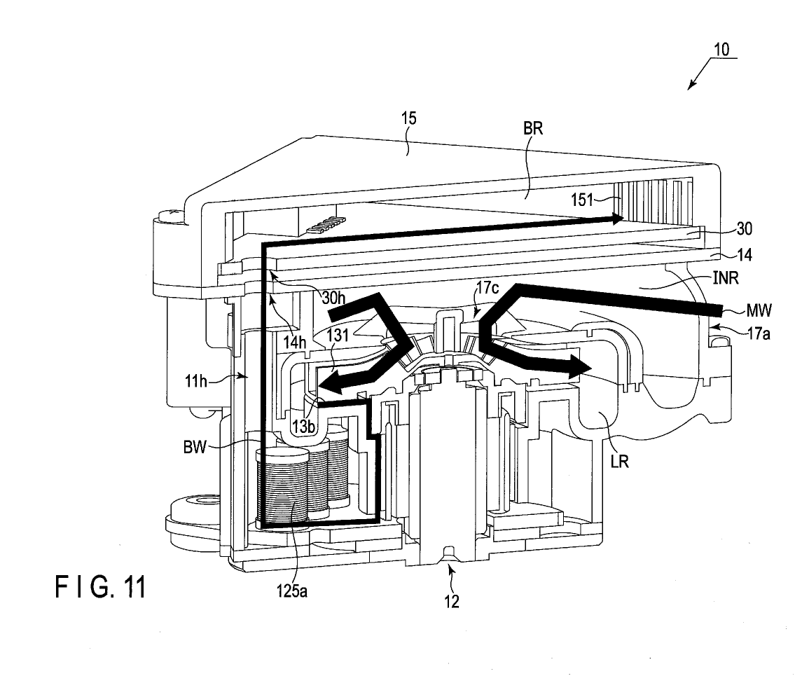

Furthermore, predetermined gaps are formed between the undersurface 13b of the fan 13 and housing member 11a constituting the accommodation chamber LR, and between the housing member 11a and motor 12. The air inside these gaps is, as will be described later by using FIG. 11, introduced into a circuit chamber BR covered with the board cover 15 through flow path holes 11h, 14h, and 30h respectively formed in the housing member 11a, intake cover 14, and circuit board 30, and can be discharged into the atmospheric air from an atmospheric hole 151 formed in the board cover 15.

[Assembly Process]

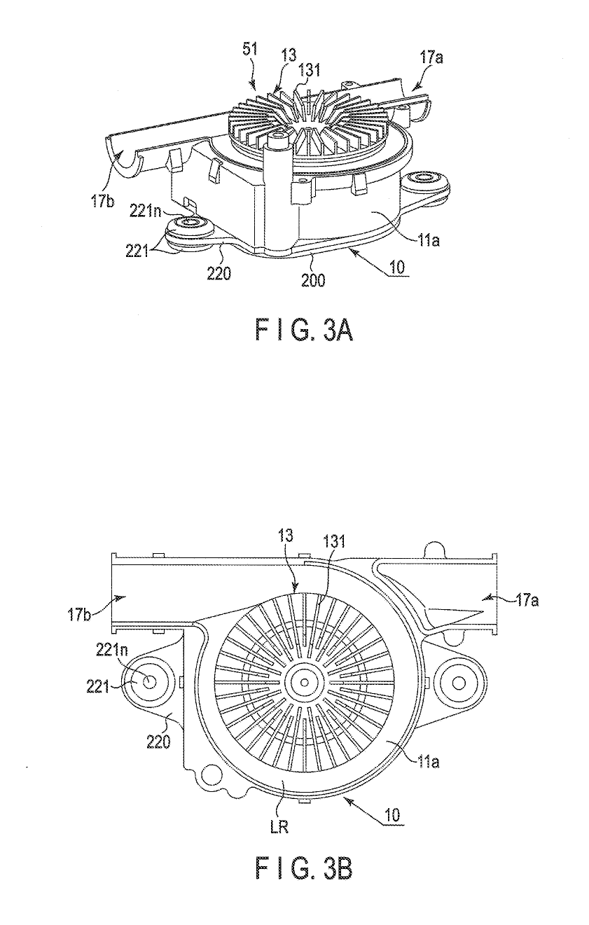

An assembly process of the blower device 10 according to the first embodiment will be described below by using FIG. 3A and FIG. 3B to FIG. 7A and FIG. 7B.

As shown in FIG. 3A and FIG. 3B, the housing member 11a includes part of the intake port 17a, part of exhaust port 17b, and part of the accommodation chamber LR. The part of the exhaust port 17b communicates with the accommodation chamber LR, and the fan unit 51 provided with the fan 13 is accommodated in the accommodation chamber LR.

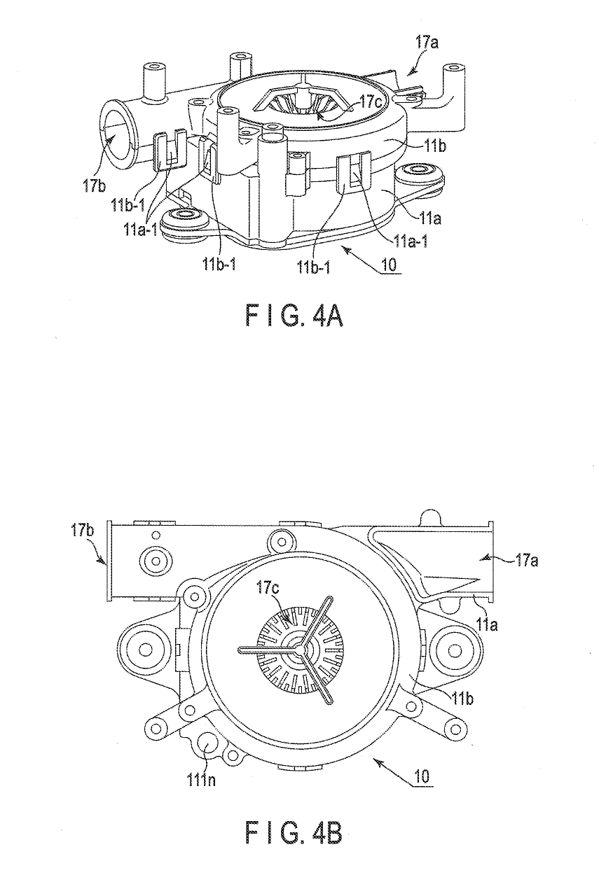

As shown in FIG. 4A and FIG. 4B, the housing member 11b is fixed on the housing member 11a. The housing member 11b includes part of the exhaust port 17b, part of the accommodation chamber LR, and opening 17c positioned at the central part of the accommodation chamber LR. The housing member 11b is fixed on the housing member 11a, whereby the exhaust port 17b and the accommodation chamber LR are formed. In the housing members 11a and 11b, engaging sections 11a-1 and 11b-1 respectively provided on the side surfaces of the housing members 11a and 11b engage each other, and are fixed to each other with an attaching screw 111n.

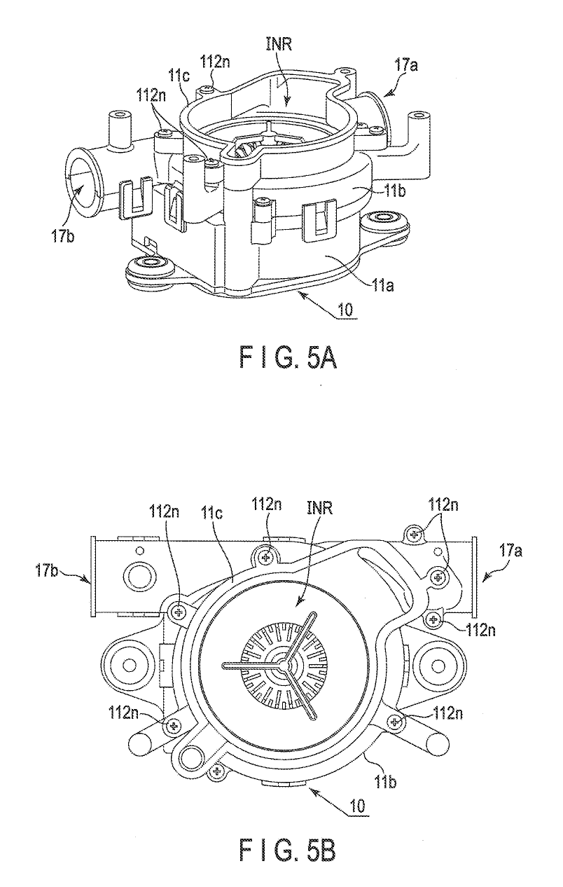

As shown in FIG. 5A and FIG. 5B, the housing member 11c is fixed on the housing member 11b. The housing member 11c includes part of the intake port 17a and intake chamber INR communicating with the intake port 17a. The housing member 11c is fixed on the housing member 11b, whereby the intake port 17a is formed. The housing member 11c is fixed to the housing member 11b with attaching screws 112n.

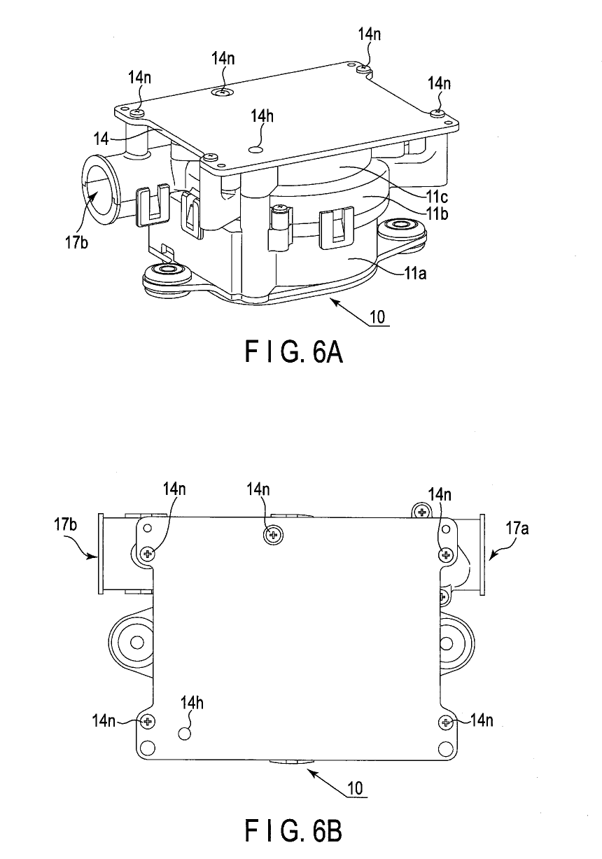

As shown in FIG. 6A and FIG. 6B, the intake cover 14 made of, for example, a metal is fixed on the housing member 11c, and the intake chamber INR is sealed up by the intake cover 14. The intake cover 14 is fixed to the housing member 11c with attaching screws 14n. Further, at a position in the peripheral part of the intake cover 14 and corresponding to a position above the flow path hole 11h provided in the housing 11, a flow path hole 14h configured to constitute the bypass flow path to be described later is formed.

It should be noted that it is desirable that as shown in FIG. 2, the distance H11 along the axial direction between the top surface of the housing member 11c provided with the opening 17c and intake cover 14 be provided in such a manner as to have a value, for example, greater than or equal to 8 mm and less than or equal to 20 mm. By setting the distance H11 in this manner, as will be described later, it is possible to sufficiently cool the circuit components by means of the air introduced into the intake chamber INR through the intake cover 14, and heat sinks 20a, 20b, and 20c.

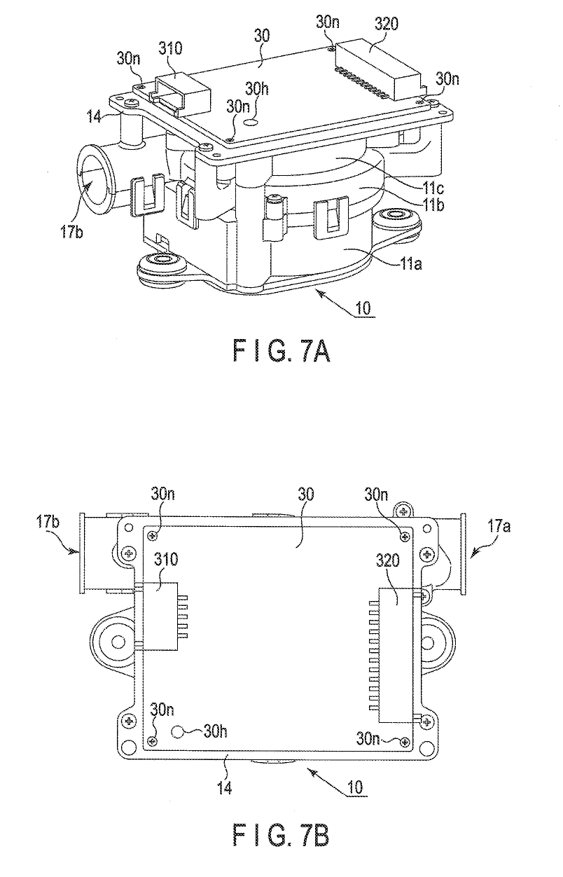

As shown in FIG. 7A and FIG. 7B, the circuit board 30 is arranged above the intake cover 14. The control circuit 31, power MOS-FET 32, and various types of connectors 310 and 320 are arranged on the circuit board 30. The circuit board 30 is fixed to the intake cover 14 with attaching screws 30n through the heat-radiation members 20a to 20c. Further, at a position in the peripheral part of the circuit board 30 and corresponding to a position above the flow path hole 14h formed in the intake cover 14, a flow path hole 30h configured to constitute the bypass flow path to be described later is formed.

After this, the board cover 15 shown in FIG. 1 and FIG. 2 is provided in such a manner as to cover the circuit board 30, and the circuit board 30 is covered with the board cover 15. The board cover 15 is fixed to the intake cover 14 with attaching screws 15n.

[Electrical Configuration]

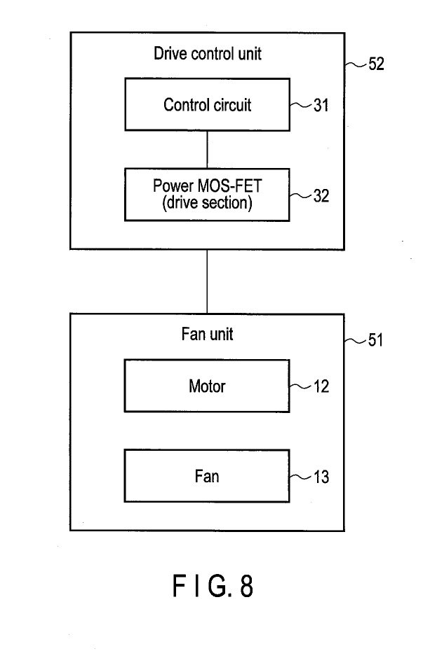

FIG. 8 schematically shows the configuration of the control system of the blower device 10 according to the first embodiment.

As shown in FIG. 8, the electrical configuration of the control system of the blower device 10 is constituted of the fan unit 51 including the motor 12 provided with the fan 13, and drive control unit 52 configured to control drive of the fan unit 51. The drive control unit 52 includes a power MOS-FET 32 configured to switch the drive electric power used to drive the motor 12, and control circuit 31 configured to control the operation of the power MOS-FET 32.

The power MOS-FET 32 is, for example, a power MOS-FET or the like of the high-voltage system, one end of a current path thereof not shown is electrically connected to a predetermined electric power source through a connector 310 or connector 320, the other end thereof is electrically connected to the coil 125, and control terminal thereof is electrically connected to the control circuit 31.

The control circuit 31 transmits a control signal to the control terminal of the power MOS-FET 32 on the basis of a drive status or the like of the fan unit 51, and controls the electric power to be supplied to the motor 12. Accordingly, the control circuit 31 may include a controller or the like configured to control, for example, the operation of the power MOS-FET 32.

[Air-Blowing Operation]

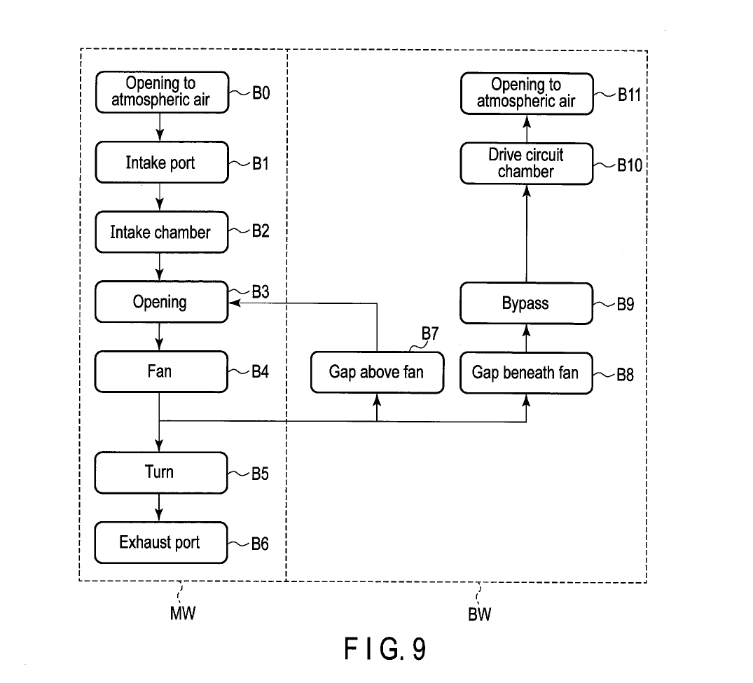

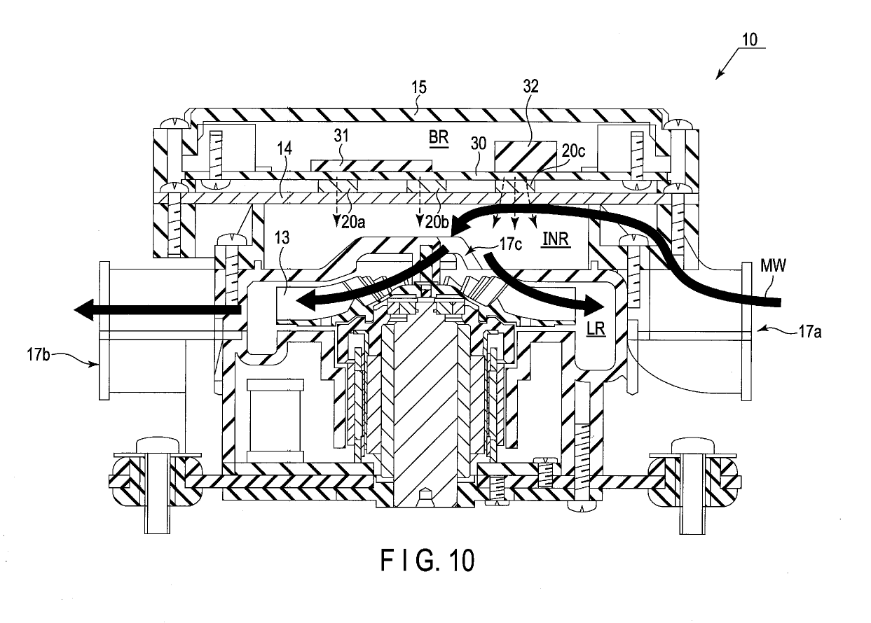

In the configuration described above, an air-blowing operation of the blower device 10 according to the first embodiment will be described below in detail by using FIG. 9 to FIG. 11. FIG. 9 is a flowchart showing the exhaust air flow paths of an air-blowing operation to be carried out by the blower device 10 according to the first embodiment. FIG. 10 is a view for explaining the main exhaust air flow path MW of FIG. 9. FIG. 11 is a view for explaining the bypass exhaust air flow path BW of FIG. 9. In the descriptions, descriptions will be given according to the flowchart of FIG. 9.

When the motor 12 is driven by the control unit 52, the fan 13 is rotated, and the pressure inside the blower device 10 becomes a negative pressure as compared with the outside atmospheric pressure, whereby the external air is introduced into the intake chamber INR from the intake port 17a (B0 to B2).

The air introduced into the intake chamber INR is further introduced into the accommodation chamber LR through the opening 17c of the housing member 11b, turns in the accommodation chamber LR, and is discharged from the exhaust port 17b to the outside with a predetermined output (blast pressure and blast flow rate) (B3 to B6). The above-mentioned flow path BO to B6 constitute the main flow path MW of the air flow paths formed by the blower device 10.

Here, as shown in FIG. 10, the external air introduced into the intake chamber INR from the intake port 17a is brought into contact with the intake cover 14 as indicated by the solid arrow, absorbs the heat of the intake cover 14, passes through the accommodation chamber LR, and is then discharged from the exhaust port 17b. Accordingly, as indicated by the dashed arrows, it is possible to radiate the heat conducted from the control circuit 31 and power MOS-FET 32 which are heating elements to the intake cover 14 through the heat sinks 20a, 20b, and 20c to the air inside the intake chamber INR, and thereby cool the control circuit 31 and power MOS-FET 32. As described above, according to this embodiment, it is possible to discharge the heat generated from the control circuit 31 and power MOS-FET 32 from the exhaust port 17b, and hence it is possible to prevent the temperature of the coil 125 of the motor 12 from being raised by the heat generated from the control circuit 31 and power MOS-FET 32. Accordingly, it is possible to prevent the output of the blower device 10 from being lowered.

Returning to FIG. 9, part of the air introduced into the accommodation chamber LR by the operation of the fan 13 returns to the opening 17c through the gap between the blades 131, i.e., the top surface of the fan 13 and housing member 11b constituting the accommodation chamber LR, and is introduced again into the fan 13 (B7).

On the other hand, as shown in FIG. 11, part of the air introduced into the accommodation chamber LR by the operation of the fan 13 is, as indicated by the arrow BW, introduced into the gap between the undersurface 13b of the fan 13 and housing member 11a, and gap between the housing member 11a and motor 12, and the air in these gaps is led to the inside of the housing member 11a in which the separate coil 125a is provided.

The air inside the housing member 11a is introduced into the circuit chamber BR through the flow path hole 11h provided in the housing member 11a, and flow path holes 14h and 30h respectively formed in the intake cover 14 and circuit board 30. Accordingly, the separate coil 125a is cooled by the flow path BW of the air led to the inside of the housing 11a and, furthermore, the control circuit 31 and power MOS-FET 32 are cooled by the flow path BW of the air introduced into the circuit chamber BR. The air inside the circuit chamber BR is discharged into the atmospheric air from the atmospheric hole 151 formed in the board cover 15 (FIG. 9, B8 to B11). The flow path B8 to B11 shown in FIG. 9 constitutes the bypass flow path (leakage flow path) BW of the air flow paths formed by the blower device 10.

[Function and Advantage]

According to the above-mentioned first embodiment, the intake chamber INR is sealed up by the intake cover 14 which is a heat sink member, and is arranged in the flow path of the air flowing from the intake port 17a to the fan 13 (FIG. 2). Accordingly, the heat generated from the control circuit 31 and power MOS-FET 32 is radiated to the air inside the intake chamber INR through the circuit board 30, heat sinks 20a to 20c, and intake cover 14, and is released from the intake chamber INR to the outside by the external air introduced from the intake port 17a into the intake chamber INR. Accordingly, it is possible to discharge the heat generated from the control circuit 31 and power MOS-FET 32 from the exhaust port 17b, and hence it is possible to prevent the temperature of the coil 125 of the motor 12 from being raised by the heat generated from the control circuit 31 and power MOS-FET 32, and prevent the output of the blower device 10 from being lowered.

Moreover, the intake chamber INR is arranged between the drive control unit 52 including the control circuit 31 and power MOS-FET 32 and coil 125 of the motor 12, and hence it is possible to physically separate the drive control unit 52 and coil 125 from each other. Therefore, according to this embodiment, it is possible to prevent the temperature of the coil 125 of the motor 12 from being raised by the operation heat generated from the control circuit 31 and power MOS-FET 32, and prevent the output of the motor 12 from being lowered.

Furthermore, the air introduced into the gap between the undersurface 13b of the fan 13 and housing member 11a constituting the accommodation chamber LR is introduced into the circuit chamber BR through the bypass flow path BW (FIG. 11, B8 to B11 of FIG. 9). Accordingly, it is possible to cool the coil 125, separate coil 125a, and drive control unit 52 inside the circuit chamber BR which are heating elements also by the air flowing along the bypass flow path BW.

Further, by the aforementioned cooling effect, the scope of choices of the power MOS-FET 32 which is an heating element increases, and a power MOS-FET 32 of a smaller size can be applied, and hence the circuit components of the circuit board 30 can be made smaller. Furthermore, the temperature margin of the power MOS-FET 32 which is an heating element can be made wider, and hence the reliability can be improved.

Moreover, the heat released into the intake chamber INR warms the air introduced into the intake chamber INR, and is discharged into the atmospheric air from the exhaust port 17b through the main flow path MW. Here, when the blower device 10 is applied to a blower device or the like used for CPAP for medical treatment of a sleep-apnea syndrome, it is possible to warm the air for respiration to be supplied from the exhaust port 17b or body-worn attachment for respiration to be worn on the respiratory organ such as a mouth or the like by the endothermic effect obtained at the time of cooling of the drive control unit 52. Accordingly, it is possible to prevent the temperature of the air discharged from the exhaust port 17b from becoming too low as compared with the body temperature of the patient, and reduce the temperature shock occurring due to the temperature difference.

### Second Embodiment (Example of Further Inclusion of Fin Structural Member)

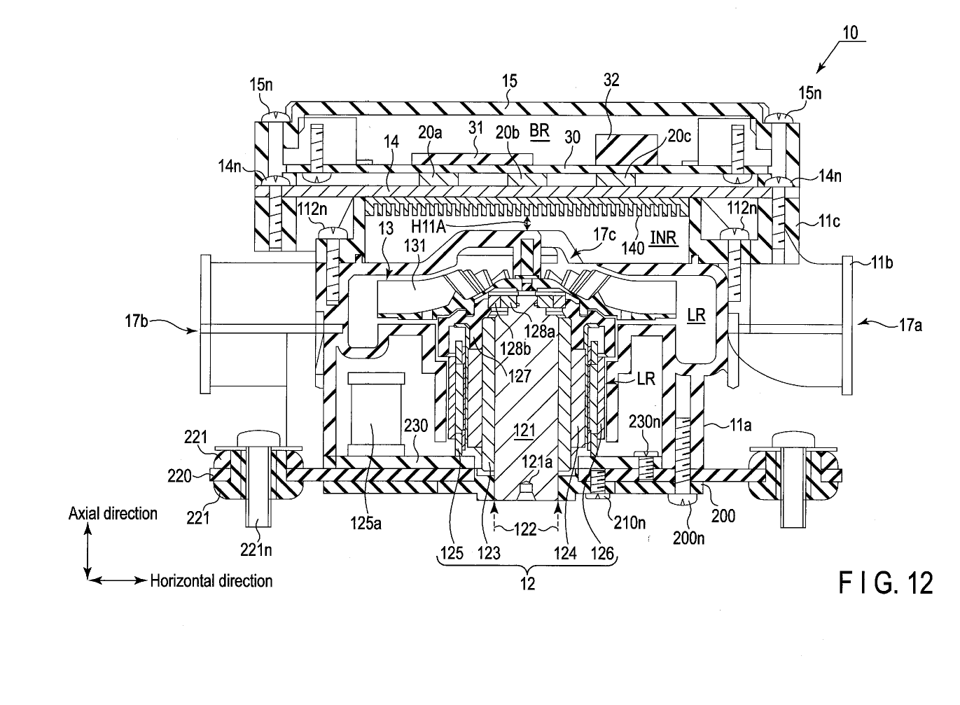

Next, a blower device 10A according to a second embodiment will be described below by using FIG. 12. FIG. 12 is a cross-sectional view showing the blower device 10A according to the second embodiment. The second embodiment is an example of a blower device 10A further provided with a fin structural member to be described later.

[Structure]

As shown in FIG. 12, in comparison with the blower device 10 according to the aforementioned first embodiment, the blower device 10A is further provided with a fin structural member 140 having a corrugated cross-sectional shape on the intake cover 14 on the intake chamber INR side. By further including the fin structural member 140, it is possible to increase the surface area for radiating the heat generated from the drive control unit 52 to the inside of the intake chamber INR, and enhance the endothermic effect to be obtained by the above-mentioned main flow path MW.

Further, it is possible to make the distance H11A between the top surface of the housing member 11c provided with the opening 17c and fin structural member 140 in the axial direction less than the distance H11 according to the first embodiment, and it is desirable that the distance H11A be provided in such a manner as to have a value, for example, greater than or equal to 5 mm and less than or equal to 15 mm.

Other structures are substantially identical to the above-mentioned first embodiment, and hence their detailed descriptions are omitted. Further, the operation is also substantially identical to the above-mentioned first embodiment, and hence a detailed description thereof is omitted.

[Function and Advantage]

According to the structure and operation of the blower device 10A associated with the second embodiment, at least a function and advantage identical to the first embodiment can be obtained.

Furthermore, the blower device 10A according to the second embodiment is further provided with a fin structural member 140 having a corrugated cross-sectional shape on the intake cover 14 on the intake chamber INR side. By further including the fin structural member 140, it is possible to increase the surface area for radiating the heat generated from the drive control unit 52 to the inside of the intake chamber INR, and enhance the endothermic effect to be obtained by the above-mentioned main flow path MW.

### Modification Example

The embodiments of the present invention are not limited to the blower devices 10 and 10A according to the above-mentioned first and second embodiments, and can be variously modified as the need arises.

For example, the material constituting the housing member 11c, intake cover 14, fin structural member 140, and board cover 15 may be made of a material (aluminum or the like) having excellent thermal conductivity. By forming the above-mentioned configuration out of a material having higher thermal conductivity, it becomes possible to further enhance the heat radiation effect to be obtained by both the main flow path MW and bypass flow path BW.

Further, the intake cover 14 and heat sinks 20a to 20c may be formed integral with each other by using the same structural member instead of separately forming the intake cover 14 and heat sinks 20a to 20c by using different structural members. Furthermore, the intake cover 14 and heat sinks 20a to 20c formed integral with each other may be formed of a material (aluminum or the like) having good thermal conductivity.

Furthermore, the intake cover 14 and fin structural member 140 may be formed integral with each other as one and the same member in the same manner, and the intake cover 14 and fin structural member 140 formed integral with each other may be formed of a material (aluminum or the like) having good thermal conductivity.

It should be noted that the usage of the blower devices 10 and 10A disclosed in these embodiments is not limited to CPAP for medical treatment of a sleep-apnea syndrome. The blower devices 10 and 10A are widely applicable to other usage items, for example, medical usage or the like for an artificial respirator.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A blower device comprising:
a housing including an intake chamber configured to take in external air from an intake port, an accommodation chamber communicating with the intake chamber through an opening, and an exhaust port configured to discharge the air inside the accommodation chamber to the outside;
a motor provided in the accommodation chamber of the housing and including a coil;
a fan provided on a rotating shaft of the motor and configured to introduce the air inside the intake chamber from the opening into the accommodation chamber and blow the air from the accommodation chamber to the exhaust port;
a sealing member configured to seal up the intake chamber; and
a circuit board which is provided above the sealing member and on which circuit components configured to drive the motor are arranged.

2. The blower device of claim 1, wherein
the intake chamber is arranged in a flow path of air flowing from the intake port to the fan.

3. The blower device of claim 1, further comprising heat-radiation members provided between the sealing member and the circuit board.

4. The blower device of claim 3, wherein
the sealing member and the heat-radiation members are formed integral with each other, and the sealing member and the heat-radiation members contain aluminum.

5. The blower device of claim 1, further comprising:
a separate coil electrically connected to the coil and functioning as an inductor; and
a board cover arranged in such a manner as to cover the circuit board and constituting a circuit chamber accommodating therein the circuit components and the circuit board.

6. The blower device of claim 5, further comprising a flow path of air introduced into the circuit chamber through a gap between an undersurface of the fan and the housing constituting the accommodation chamber and a gap between a side surface of the motor and the housing, and via the separate coil, and is then discharged into the external atmospheric air.

7. The blower device of claim 1, further comprising a fin member whose cross section includes a corrugated shape on the sealing member of the intake chamber side.

8. The blower device of claim 2, further comprising a fin member whose cross section includes a corrugated shape on the sealing member of the intake chamber side.

9. The blower device of claim 3, further comprising a fin member whose cross section includes a corrugated shape on the sealing member of the intake chamber side.

10. The blower device of claim 4, further comprising a fin member whose cross section includes a corrugated shape on the sealing member of the intake chamber side.

11. The blower device of claim 5, further comprising a fin member whose cross section includes a corrugated shape on the sealing member of the intake chamber side.

12. The blower device of claim 6, further comprising a fin member whose cross section includes a corrugated shape on the sealing member of the intake chamber side.
